(19) United States
(12) Patent Application Publication
(10) Pub. No.: US 2014/0264343 A1
(43) Pub. Date: Sep. 18, 2014

(54) DEVICE ARCHITECTURE AND METHOD FOR TEMPERATURE COMPENSATION OF VERTICAL FIELD EFFECT DEVICES

(71) Applicant: D3 Semiconductor LLC, Addison, TX (US)

(72) Inventor: Thomas E. Harrington, III, Carrollton, TX (US)

(73) Assignee: D3 SEMICONDUCTOR LLC, Addison, TX (US)

(21) Appl. No.: 14/210,038

(22) Filed: Mar. 13, 2014

Related U.S. Application Data
(60) Provisional application No. 61/778,698, filed on Mar. 13, 2013.

(51) Int. Cl. H01L 29/78; H01L 29/66

(52) U.S. Cl. CPC H01L 29/7803; H01L 29/66712
USPC 257/51; 438/238

(57) ABSTRACT

A field effect device is disclosed that provides a reduced variation in on-resistance as a function of junction temperature. The field effect device, having a source junction, gate junction and drain junction, includes a resistive thin film adjacent the drain junction wherein the resistive thin film comprises a material having a negative temperature coefficient of resistance. The material is selected from one or more materials from the group consisting of doped polysilicon, amorphous silicon, silicon-chromium and silicon-nickel, where the material properties, such as thickness and doping level, are chosen to create a desired resistance and temperature profile for the field effect device. Temperature variation of on-resistance for the disclosed field effect device is reduced from the temperature variation for a similar field effect device without the resistive thin film.

### CROSS-REFERENCE TO RELATED APPLICATION

This application claims priority benefit from U.S. Provisional Application No. 61/778,698 filed Mar. 13, 2013. The patent application identified above is incorporated here by reference in its entirety to provide continuity of disclosure.

### FIELD OF THE INVENTION

The present invention relates generally to the methods and techniques for reducing the temperature variation of resistance of a vertical MOSFET devices.

### BACKGROUND OF THE INVENTION

For many years, manufacturers and developers of high performance power electronics have sought to improve power-handling density and manage device heat dissipation of discrete electronic components.

Vertical MOSFETs have an on-resistance (“RdsOn”) that increases monotonically and super-linearly with temperature. As the on-resistance increases, so does the power dissipated for a given drain current (I_{d}) according to the power equation: Power=I_{d}²×RdsOn. Power dissipation in turn causes the MOSFET junction temperature to increase, which further increases the on-resistance. If heat dissipation is sufficient, then the RdsOn will increase until thermal equilibrium is reached in the MOSFET. If heat dissipation system is insufficient, then the MOSFET will experience thermal runaway.

Reduction in RdsOn in modern vertical MOSFET devices has resulted in significant improvements in power supply efficiency. However, the RdsOn still increases with temperature. Systems incorporating these devices, especially systems that are operated at a variety of duty cycles and/or a variety of ambient temperatures, would benefit greatly from an RdsOn that demonstrates reduced variation with temperature.

### SUMMARY

The present disclosure is a field-effect device architecture that reduces the temperature variation of resistance. In particular, this disclosure provides a method and an apparatus for reducing the variation of RdsOn due to increasing temperature.

According to a preferred embodiment, a resistor having a negative temperature coefficient (“NTC”) is connected in series with a vertical MOSFET to obtain a more stable resistance variation with temperature. Also, variation of the device resistance with temperature is significantly reduced.

In a preferred embodiment, a MOSFET vertical field-effect device is constructed on an epitaxial Si wafer with an n+ doped base substrate.

In another embodiment, a MOSFET vertical field-effect device is constructed on a non-epitaxial Si wafer with an n− doped substrate.

The apparatus finds applicability in both n-channel and p-channel devices operating in either depletion or enhancement mode.

### BRIEF DESCRIPTION OF THE DRAWINGS

FIG. 1A illustrates a prior art field-effect device.

FIG. 1B illustrates a resistive path for the on-resistance of a prior art field effect device.

FIG. 2A illustrates a preferred embodiment of a field-effect device having an integrated negative temperature coefficient resistor.

FIG. 2B illustrates a resistive path for on-resistance of a preferred embodiment of a field effect device having an integrated negative temperature coefficient resistor.

FIG. 3 is an exemplary graph of normalized on-resistance as a function of junction temperature for a prior art vertical field effect device, normalized on-resistance as a function of junction temperature for a preferred embodiment of a vertical field effect device with an incorporated NTC resistor and, a temperature dependence curve of a stand-alone negative temperature coefficient resistor.

FIG. 4A is a flow diagram of a preferred embodiment of a method for constructing a vertical field effect device with a reduced variation of on-resistance with temperature.

FIG. 4B is a flow diagram of an alternate embodiment of a method for constructing a vertical field effect device with a reduced variation of on-resistance with temperature.

FIG. 4C is a flow diagram of an alternate embodiment of a method for constructing a vertical field effect device with a reduced variation of on-resistance with temperature.

FIG. 4D is a flow diagram of an alternate embodiment of a method for constructing a vertical field effect device with a reduced variation of on-resistance with temperature.

FIG. 4E is a flow diagram of an alternate embodiment of a method for constructing a vertical field effect device with a reduced variation of on-resistance with temperature.

FIG. 4F is a flow diagram of an alternate embodiment of a method for constructing a vertical field effect device with a reduced variation of on-resistance with temperature.

FIG. 5 is a flow diagram of a preferred embodiment of a method to construct a negative temperature coefficient resistor.

### DETAILED DESCRIPTION

Vertical semiconductor devices are semiconductor constructs (for example MOSFETs, IGBTs and diodes) where the primary direction of current flow is vertical, that is, from top to bottom or bottom to top or both. Power discrete semiconductor devices are often built with such a vertical architecture.

“On-resistance” (RdsOn) is the resistance of a semiconductor device when it is biased in the “on-state” by applying voltages and/or currents to its electrodes. For example, a MOSFET has a gate electrode, a source electrode and a drain electrode with a drain-source voltage (Vds) applied between the drain electrode and source electrodes and a gate-source voltage (Vgs) applied between the gate and source electrodes. “On-state” means that current (Id) from the source electrode to the drain electrode is enabled by the gate-source voltage. For a power MOSFET, for example, RdsOn is defined as:

RdsOn=Id/Vds Eq. 1
when the drain-source voltage (Vds) is typically set to a value between 0.1V and 5V, and the gate-source voltage (Vgs) is typically set to 10V.

Power MOSFETS including non-charge compensated vertical field effect devices and charge-compensated vertical field effect devices (e.g., super junction MOSFETS), like some other vertical semiconductor devices are positive temperature coefficient devices. In general, positive temperature coefficient devices have a device resistance which increases with increasing temperature.

Conversely, NTC devices have a resistance that decreases with increasing temperature. One example of an NTC device is an NTC resistor.

FIG. 1A shows a cross-sectional view of vertical MOSFET device 100 as known in the prior art. Vertical field-effect device 100, having a top surface 121 and a bottom surface 122, includes a source electrode 102, a drain electrode 103 and a gate electrode 101. The gate electrode controls the current flow between source electrode 102 and drain electrode 103. Vertical field-effect device 100 further includes an “n+” drain region 106 having a metal layer 107 adjacent the bottom surface to form drain electrode 103. N+ drain region 106 is in contact with “n−” drift region 105. N− drift region 105 is in further contact with “p−” type body region 140.

N+ source region 109 is adjacent the “p” type body regions. The p type body regions include p− body 140, “p+” body 141, and p+ body-contacting region 142. p+ body-contacting region 142 contacts source metal layer 108 which electrically shorts n+ source region 109 to p+ body-contacting region 142 to avoid accidental excitation of a parasitic bipolar junction transistor which is formed between the n+ source region, the p type body regions and the drain electrode 103. Source metal layer 108 is in further contact with a source electrode 102. The n− drift region 105 is below p-type body regions 140, 141, 142 and adjacent to n+ drain region 106.

Gate region 113 contacts an insulation oxide layer 112 adjacent n− drift region 105, p− body region 140, n+ source region 109 and insulation layer 111. Gate region 113 is filled with a gate material adjacent gate oxide layer 112. Gate region 113 is in electrical contact with gate electrode 101. Gate oxide layer 112 is also adjacent n− drift region 105. A gate material commonly used in MOSFET devices is polycrystalline silicon (polysilicon).

FIG. 1B shows the path for on-resistance of a prior art device. On-resistance is the total resistance between the source and the drain during the on-state of the device as in Eq. 1. The path for on-resistance is shown at path 150. For the vertical field effect device 100, the on-resistance is given by the series resistive combination:

RdsOn=Rₙ+R_{CH}+Rₐ+Rⱼ+R_{D}+R_{S} Eq. 2

where RdsOn is the on-resistance, Rₙ, 151, is the resistance of n+ source region 109, and R_{ch} 152 is the resistance of the channel formed in the p− portion of the p-type body region 140. Rₐ 153 is the surface resistance of the n− drift region which is modulated by the applied gate-source voltage. JFET region 130 is a portion of n− drift region 105 between the surfaces 132 of p type body (p− body) region 140. As a drain voltage is supplied, the depletion region expands outward from the junction at surfaces 132, which causes and increases the resistance 154 (R_{d}) due to constriction of the n− drift region between surfaces 132. Rⱼ 154 is the resistance of the JFET region. R_{D} 155 is the resistance between the JFET region 130 to the top of n+ drain region 106. R_{D} is the resistance of the n-drift region and is the most dominant factor of RdsOn in high voltage MOSFETs. R_{S} 156 is the resistance of the n+ drain region. In low voltage MOSFETs, where the breakdown voltage is below about 50V, R_{S} also has a large effect on the on-resistance. Additional on-resistance can arise from a non-ideal contact between the various regions as well as from the electrode leads used to connect the device to the package.

RdsOn increases with temperature because the mobility of the holes and electrons decrease as the temperature rises. RdsOn of an n− channel power MOSFET device can be estimated with the following equation:

$$RdsOn ( T ) = RdsOn ( 300 ° K ) {( \frac{T}{300} )}^{β} \qquad Eq . 3$$

where T is a device temperature in Kelvin, β is a temperature coefficient and RdsOn(T) is the on-resistance at the device temperature T. The temperature coefficient is positive and commonly in the range of 2.0 to 2.5 for MOSFET devices.

FIG. 2A shows a cross-sectional view of a preferred embodiment of vertical field effect device 200 with RdsOn temperature compensation. A top surface 221 and a bottom surface 222 are provided, including source electrode 202, drain electrode 203 and gate electrode 201. Gate electrode 201 controls the current flow between source electrode 202 and drain electrode 203. Device 200 also includes an n+ drain region 206. Adjacent the n+ drain region 206 is a resistive layer 220. Resistive layer 220 exhibits a negative temperature coefficient. Adjacent resistive layer 220 is metal layer 207. Metal layer 207 is attached to drain electrode 203. N+ drain region 206 is in contact with n− drift region 205. N− drift region 205 is in contact with p type body regions 240, 241, 242.

N+ source region 209 is adjacent p type body regions. The p type body regions include p− body 240, p+ body 241 and p+ body contacting region 242. P+ body-contacting region 242 contacts source metal layer 208 which electrically shorts n+ source region 209 to p type body regions 240, 241, 242. Source electrode 202 is attached to source metal layer 208.

Gate region 213 is adjacent to gate oxide layer 212 which is adjacent n− drift region 205, p− body region 240, n+ source region 209 and insulation layer 211. Gate region 213 is in electrical contact with gate electrode 201. Gate oxide layer 212 is also adjacent n− drift region 205.

FIG. 2B shows the path 250 for on-resistance of a preferred embodiment device. For device 200, the on-resistance is given by the equation:

RdsOn=Rₙ+R_{CH}+Rₐ++R_{D}+R_{S}+R_{NTC} Eq. 4

where RdsOn is the on-resistance, Rn 251 is the resistance of n+ source region 209, R_{ch} 252 is the resistance of the channel formed in the p− body region 240. JFET region 230 is a portion of n− drift region 205 between the surfaces 232 of p type body (p− body) region 240. As a drain voltage is supplied, the depletion region expands outward from the junction at surfaces 232, which creates and increases resistance (Rⱼ) due to constriction of the n− drift region between surfaces 232. Rⱼ 254 is the resistance of the JFET region. R_{D} 255 is the n− drift region resistance between the JFET region 230 to the top of n+ drain region 206. Rₐ 253 is the surface resistance of the n− drift region which is modulated by the applied gate-source voltage. R_{S} 256 is the resistance of the n+ drain region. R_{NTC} 257 is the resistance of resistive layer 220 having a negative temperature coefficient which characterizes the decrease in resistance of R_{NTC} 257 as temperature increases.

In a preferred embodiment of a vertical MOSFET device, a reduced variation of the RdsOn resistance with temperature is accomplished by adding an NTC resistor in series with the MOSFET.

In a preferred embodiment, the NTC resistor is provided by resistive layer 220 and is comprised of a thin film made of polysilicon (or amorphous silicon, deposited by sputtering for example) which is doped in-situ. In another embodiment, resistive layer 220 is a thin film comprised of a polysilicon (or amorphous silicon) which is doped by implantation and subsequently annealed, with the thickness of the polysilicon or amorphous silicon layer in a range of approximately 100 angstroms to approximately 4000 angstroms.

The doping level of the polysilicon or amorphous silicon thin film is preferably in the range of about 1 e17 atoms/cm³ to about 1 e21 atoms/cm³. These values can vary by as much as ±5%. The dopants in the polysilicon or amorphous silicon thin film are from the group of elements consisting of arsenic, phosphorus, boron or any combination of these elements required to achieve a desired resistance value for the resistive layer at a base temperature (such as 25° C.) and a desired negative temperature coefficient of resistance value.

In another embodiment, resistive layer 220 is a metalized resistive thin film made of silicon-chromium. The silicon percentage of the silicon-chromium film is preferably in the range of about 40% to about 80%. These values can vary by as much as ±5%. The thickness of the silicon-chromium film is in the range of approximately 25 angstroms to approximately 2000 angstroms as required to achieve the desired sheet resistance value for the resistive layer at a base temperature (such as 25° C.) and the desired negative temperature coefficient of resistance value. These values can vary by as much as +10%.

In another embodiment, resistive layer 220 is a metalized resistive thin film made of silicon-nickel. The silicon percentage of the silicon-nickel film is preferably in the range of about 40% to about 80%. The thickness of the silicon-nickel film is in the range of approximately 25 angstroms to approximately 2000 angstroms as required to achieve the desired sheet resistance value for the resistive layer at a base temperature (such as 25° C.) and the desired negative temperature coefficient of resistance value. These values can vary by ±10%.

FIG. 3 is a graph showing an illustrative example of the effect of including resistive layer 220 in a vertical field-effect device. Graph 300 is a plot of resistance in ohms as a function of junction temperature of the device. Graph 300 includes three curves. The curves are plotted for junction temperatures in a range from about −25° C. to about 150° C. Curve 310 is a plot of on-resistance of a MOSFET device exhibiting the temperature dependence of Eq. 3 for 13=2.0 ranging from about 0.8 ohms at −25° C. to about 2.25 ohms at 150° C. Resistance values can vary by as much as ±5%. Curve 320 is a plot of the resistance of a negative temperature coefficient resistive layer. The resistive layer exhibits a temperature dependence ranging from about 1.6 ohms at −25° C. to an asymptotic value of about 1.0 ohm at temperatures of 125° C. and above. Curve 330 is a plot of the composite on-resistance of a composite device having the resistive layer in series contact with the MOSFET device. The composite on-resistance exhibits a temperature dependence ranging from about 2.4 ohms at −25° C. to about 3.2 ohms at 150° C. with a total variation of 0.8 ohms across the temperature range −25° C. to 150° C. In this example, the composite resistance of the MOSFET RdsOn with NTC resistor 220 demonstrates a more flat and stable resistance profile as compared to a MOSFET without the NTC resistor. The composite resistance in this example varies about 32% between 25° C. to 150° C., while the non-composite MOSFET RdsOn varies almost 95%. Thus the variation of on-resistance RdsOn with temperature of the composite device is reduced by about 50% compared to the temperature variation of on-resistance for a MOSFET device without the resistive layer.

Referring to FIG. 4A, a preferred method 400 of constructing a preferred embodiment of a field effect device and a substrate is described. At step 402, a wafer with an n-epitaxial layer on top of an n+ substrate is selected as the semiconductor substrate. In such a wafer, n− epitaxial layer is doped to the correct n− level during the epitaxial layer growth. At step 404, a vertical field effect device is constructed on the n− epitaxial layer. In the preferred embodiment, a MOSFET is the vertical field effect device.

At step 406, a backgrind is conducted on the second side to reduce wafer thickness.

At step 407, an NTC resistive thin film is grown or deposited on the n+ substrate. For example, the NTC resistive thin film can be made of polysilicon deposited or grown on the second side, or amorphous silicon deposited by sputtering or other methods. The NTC resistive thin film may be doped in-situ.

At step 408, depending upon whether the NTC resistive thin film was doped in-situ and whether such doping is sufficient to achieve the desired negative temperature coefficient characteristics. The NTC resistive thin film may be further doped by implantation to give it a desired negative temperature coefficient of resistance. At step 409, the NTC resistive thin film is annealed (by laser or RF annealing for example).

At step 410, apply a metal layer to the NTC resistive thin film to create the drain connection.

Referring to FIG. 4B, an alternate method 411 of constructing a preferred embodiment of a field effect device and the substrate is described. At step 412, a wafer with an n− epitaxial layer on top of an n+ substrate is selected as a semiconductor substrate. At step 413, a vertical field effect device is constructed on then n-epitaxial layer. In the preferred embodiment, a MOSFET is a vertical field device. At step 414, backgrind is conducted on the second side. At step 415, an NTC resistive thin film is grown or deposited on the n+ substrate. The NTC resistive thin film is a metalized resistive thin film made of silicon-nickel or silicon-chromium, which is doped in situ to achieve the desired negative temperature coefficient. At step 416, the metalized NTC resistive thin film may be given a low temp sinter to anneal the metalized thin film. At step 418, a metal layer is applied to the NTC resistive thin film to create the drain connection.

Referring to FIG. 4C, an alternative method 425 of constructing a vertical field effect device will be described. At step 427, an n− non-epitaxial wafer is selected for the substrate.

At step 429, a vertical field effect device is constructed on the first side. At step 431, backgrind is conducted on the second side. At step 432, an n+ drain region is implanted on the second side. At step 433, the n+ drain region is annealed. At step 435, an NTC resistive thin film is grown or deposited on the second side, wherein the resistive film may be doped in-situ. At step 436, depending upon whether the NTC resistive thin film was doped in-situ and whether such doping is sufficient to achieve the desired negative temperature coefficient characteristic. The NTC resistive film may be further doped by implantation. At step 438, the NTC resistive thin film is annealed. At step 439, the second side is metalized to create the drain connection.

Referring to FIG. 4D an alternative method 440 of constructing a vertical field effect device is described. At step 441, an n− non-epitaxial wafer is selected for a substrate.

At step 443, a vertical field effect device is constructed on the first side. At step 444, backgrind is conducted on the second side.

At step 445, an n+ drain region is implanted on the second side. At step 446, the n+ drain region is annealed. At step 447, an NTC resistive thin film is grown or deposited on the second side. At step 448, the NTC resistive thin film is doped through implantation to achieve the desired negative temperature coefficient characteristic. At step 449, the NTC resistive thin film is annealed. At step 450, the second side is metalized to create the drain connection.

Referring to FIG. 4E, an alternative method 451 of constructing a vertical field effect device will be described. At step 452, an n− non-epitaxial wafer is selected for the substrate.

At step 456, a vertical field effect device is constructed on the first side. At step 457, backgrind is conducted on the second side. At step 458, an n+ drain region is implanted on the second side. At step 460, an NTC resistive thin film is grown or deposited on the second side, wherein the thin film may be doped in-situ. At step 461, depending on whether the resistive thin film is doped in-situ and whether such doping is sufficient to achieve the desired negative temperature coefficient characteristic, the NTC resistive thin film may be further doped by implantation. At step 462, the n+ drain region and the NTC resistive thin film are annealed together. At step 464, the second side is metalized to create the drain connection.

Referring to FIG. 4F, an alternative method 475 of constructing a vertical field effect device will be described. At step 477, an n− non-epitaxial wafer is selected for the substrate. At step 481, a vertical field effect device is constructed on the first side. At step 482, backgrind is conducted.

At step 483, a polysilicon or amorphous silicon NTC resistive film is grown or deposited on the n− substrate. At step 485, an n+ drain region is implanted through the NTC film. One advantage to implanting the n+ drain region through the NTC film is that the effective thickness of the NTC film will be set by the depth of the n+ drain implant. This will result in a very uniform across the wafer effective NTC film thickness due to the precise depth control of the n+ ion implant. At step 486, depending on whether the NTC film is doped in-situ and whether such doping is sufficient to achieve the desired negative temperature coefficient characteristic, the NTC resistive film may be further doped by implantation. At step 487, the NTC drain region and the NTC film are annealed together. At step 489, the second side is metalized to create the drain connection.

Referring to FIG. 5, a method 520 of selecting and forming a resistive thin film is described. At step 522, a composite on-resistance is specified for the composite device with a desired variation of on-resistance with temperature. At step 524, a set of on-resistance values are measured over a range of junction temperatures for a set of devices, and averaged to determine a device on-resistance. At step 526, a temperature dependence curve of the resistive thin film is determined by subtracting the device on-resistance from the specified composite on-resistance.

At step 528, a material is selected and further specified for the resistive thin film based on the temperature dependence curve and based on physical compatibility with the semiconductor substrate including a temperature expansion coefficient. The material can include dopants with specified doping levels. At step 530, a sheet resistance for the resistive thin film is determined for the material.

At step 532, a set of desired processing properties is determined for creating the resistive thin film. The set of desired processing properties include the desired composition, doping type and level, and thickness of the resistive thin film, which is determined by dividing the specified resistance at 25° C. by the sheet resistance. At step 533, a vertical field device is constructed on the first side of a wafer.

At step 534, the resistive thin film is grown or deposited and processed according to the material properties, the processing properties and the desired composition, doping type and level, and thickness on the side of the wafer.

At step 536, the thin film is doped in-situ or by implantation. At step 538, the thin film is annealed, if required.

In a preferred embodiment of the method, the material of the resistive thin film is selected from the group of materials including polysilicon, amorphous silicon, silicon-chromium, silicon-nickel or a combination of these materials. In another embodiment, a different material can be selected provided the material and processing properties can be derived to achieve a negative temperature coefficient of resistance.

In a first embodiment, polysilicon or amorphous silicon is selected as the material for the resistive thin film and the polysilicon is doped in-situ. In a second preferred embodiment, polysilicon or amorphous silicon is selected as the material for the resistive thin film and the polysilicon or amorphous silicon is doped by implantation and subsequently annealed. In the first embodiment and the second embodiment, the doping level of the polysilicon or amorphous silicon thin film is selected to be in the range of 1 e 17 atoms/cm³ to 1 e21 atoms/cm³ and the dopants in the polysilicon or amorphous silicon thin film are selected from the group of elements consisting of arsenic, phosphorus, boron or any combination of these elements required to achieve a desired resistance value for the resistive layer at the base temperature (25° C.) and the desired temperature dependence curve.

In a third embodiment, silicon-chromium is selected as the material of the resistive thin film. The silicon percentage of the silicon-chromium film is chosen in the range of 40% to 80% and the thin film is grown with a thickness in the range of approximately 25 A to approximately 2000 A as required to achieve the desired sheet resistance value for the resistive layer at the base temperature (such as 25° C.) and the desired temperature dependence curve.

In a fourth embodiment, silicon-nickel is selected as the material of the resistive thin film. The silicon percentage of the silicon-nickel film is chosen in the range of 40% to 80% and the thin film is grown with a thickness in the range of approximately 25 A to approximately 2000 A as required to achieve the specified resistance value for the resistive layer at the base temperature (such as 25° C.) and the desired temperature dependence curve.

The embodiments presented in this disclosure are intended to provide implementable examples of the present invention, but are not intended to limit the present invention. For example, other materials besides Si can be used as a base semiconductor material. Various ranges of doping levels for the n+ regions, n-columns, p-columns and p-type body can be employed as required.

1. A semiconductor device comprising:
a substrate;
a vertical field effect device, having a drain region, constructed on the substrate; and,
a negative temperature coefficient resistor adjacent the drain region.

2. The semiconductor device of claim 1 wherein the negative temperature coefficient resistor is polysilicon.

3. The semiconductor device of claim 2 wherein polysilicon is doped at between about 1×10¹⁷ and about 1×10²¹ atoms per cubic centimeter.

4. The semiconductor device of claim 2 wherein the polysilicon is doped with one of the group of arsenic, phosphorous, and boron.

5. The semiconductor device of claim 1 wherein the negative temperature coefficient resistor is amorphous silicon.

6. The semiconductor device of claim 5 wherein amorphous silicon is doped at between about 1×10¹⁷ and about 1×10²¹ atoms per cubic centimeter.

7. The semiconductor device of claim 5 wherein the amorphous silicon is doped with one of the group of arsenic, phosphorous, and boron.

8. The semiconductor device of claim 1 wherein the negative temperature coefficient resistor is silicon-chromium.

9. The semiconductor device of claim 8 wherein the silicon-chromium is about 40% to about 80% silicon.

10. The semiconductor device of claim 1 wherein the negative temperature coefficient resistor is silicon-nickel.

11. The semiconductor device of claim 10 wherein the silicon-nickel is about 40% to about 80% silicon.

12. The semiconductor device of claim 1 wherein the negative temperature coefficient resistor has a thickness of about 25 to about 2000 angstroms.

13. The semiconductor device of claim 1 wherein the vertical field effect device is a MOSFET.

14. The semiconductor device of claim 1 wherein the vertical field effect device is a charge compensated MOSFET.

15. A MOSFET having an n+ source region, a p− channel, a JFET region, an n− drift region and a negative temperature coefficient resistance layer, comprising:
an on-resistance defined by the equation:
RdsOn=Rₙ+R_{CH}+Rₐ+Rⱼ+R_{D}+R_{S}+R_{NTC}
where RdsOn=on-resistance;
Rₙ=resistance of the n+ source region;
resistance of the p− channel;
Rₐ=surface resistance of the n− drift region;
Rⱼ=resistance of the JFET region;
R_{d}=resistance of the n− drift region;
R_{S}=resistance of the n+ drain region; and,
R_{NTC}=resistance of the negative temperature coefficient resistance layer.

16. The MOSFET of claim 15 wherein R_{NTC} ranges from about 1.6 ohms to about 1.0 ohms at between about −25° C. and about 125° C.

17. The MOSFET of claim 15 wherein RdsOn ranges from about 2.4 ohms and about 3.2 ohms at between about −25° C. and about 125° C.

18. The MOSFET of claim 15 wherein RdsOn exhibits a total variation of about 0.8 ohms across a temperature variation of about 125° C.

19. A vertical field effect device comprising:
a positive temperature coefficient device; and,
a negative temperature coefficient resistor, connected in series and in physical contact with the positive temperature coefficient device.

20. The vertical field effect device of claim 19 wherein the positive temperature coefficient device is a MOSFET.

21. The vertical field effect device of claim 19 wherein the negative temperature coefficient resistor is polysilicon.

22. The vertical field effect device of claim 19 wherein the negative temperature coefficient resistor is amorphous silicon

23. The vertical field effect device of claim 19 wherein the negative temperature coefficient resistor is silicon-chromium.

24. The vertical field effect device of claim 19 wherein the negative temperature coefficient resistor is silicon-nickel.

25. A method of manufacturing a semiconductor device on a wafer having an n− epitaxial layer on an n+ substrate, the method comprising:
constructing a vertical field effect device on the n− epitaxial layer;
applying a negative temperature coefficient resistive layer on the n+ substrate;
doping the negative temperature coefficient resistive layer; and,
applying a metal layer to the negative temperature coefficient resistive layer.

26. The method of claim 25 wherein the step of constructing further comprises constructing a MOSFET.

27. A method of manufacturing a semiconductor device on a wafer having an n− epitaxial layer on an n+ substrate, the method comprising:
constructing a vertical field effect device on the n− epitaxial layer;
applying a negative temperature coefficient resistive layer on the n+ substrate;
annealing the negative temperature coefficient resistive layer; and,
applying a metal layer to the negative temperature coefficient resistive layer.

28. The method of claim 27 wherein the step of constructing further comprises constructing a MOSFET.

29. A method of manufacturing a semiconductor device on an n− non-epitaxial wafer comprising:
constructing a vertical field effect device on a first side of the wafer;
implanting an n+ region in a second side of the wafer;
annealing the n+ region;
applying a negative temperature coefficient resistive film on the n+ region;
implant doping the negative temperature coefficient resistive film;
annealing the negative temperature coefficient resistive film; and,
metalizing the second side.

30. The method of claim 29 wherein the step of annealing further comprises laser annealing.

31. A method of manufacturing a semiconductor device on an n− non-epitaxial wafer comprising:
constructing a vertical field effect device on a first side of the wafer;
implanting an n+ region on a second side of the wafer;
annealing the n+ region;
applying a negative temperature coefficient resistive film on the n+ region;
implant doping the negative temperature coefficient resistive film;
annealing the negative temperature coefficient resistive film; and,
metalizing the second side.

32. A method of manufacturing a semiconductor device on an n− non-epitaxial wafer comprising:
constructing a vertical field effect device on a first side of the wafer;
implanting an n+ drain region on a second side of the wafer;
applying a negative temperature coefficient resistive film on the second side;
annealing the n+ drain region and the negative temperature coefficient resistive film; and,
metalizing the second side.

33. The method of claim 32 subsequent to applying a negative temperature coefficient resistive film, implant doping the negative temperature coefficient resistive film.

34. A method of manufacturing a semiconductor device on an n− non-epitaxial wafer comprising:
constructing a vertical field effect device on a first side of the wafer;
applying a polysilicon negative temperature coefficient resistive film on a second side of the wafer;
implanting an n+ region through the negative temperature coefficient resistive film;
annealing the n+ region and the negative temperature coefficient resistive film simultaneously; and,
metalizing the negative temperature coefficient resistive film.

35. The method of claim 34 further comprising:
subsequent to implanting an n+ region, implant doping the negative temperature coefficient resistive film.

36. A method of manufacturing a semiconductor device comprising:
specifying a composite on-resistance for the semiconductor device;
specifying a required on-resistance variation for the semiconductor device;
determining an average device on-resistance for a set of non-composite semiconductor devices;
determining a temperature dependence curve for a resistive thin film;
selecting a material based on the temperature dependence curve;
determining a sheet resistive for the material;
determining a set of desired properties for the resistive thin film;
constructing a vertical field effect device on a first side of a wafer;
applying the resistive thin film to a second side of the wafer; and,
doping the resistive thin film.

37. The method of manufacturing a semiconductor device of claim 36 further comprising:
annealing the resistive thin film.
